(19) United States
(12) Patent Application Publication
(10) Pub. No.: US 2005/0253616 A1
(43) Pub. Date: Nov. 17, 2005

(54) Method and apparatus for testing and diagnosing electrical paths through area array integrated circuits

(76) Inventors: Kenneth P. Parker, Fort Collins, CO (US); Nurwati S. Devnani, Fort Collins, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/836,059

(22) Filed: Apr. 30, 2004

(51) Int. Cl. G01R 31/26

(52) U.S. Cl. 324/765

(57) ABSTRACT

A device for enabling testing electrical paths through an area array package of a circuit assembly is presented. The device may include a measurement access target on the area array package, wherein the measurement access target is connected to fill metal in the signal routing layers of the area array package. A method for testing continuity of electrical paths through an area array package of a circuit assembly is presented. In the method, one or more nodes of the circuit assembly are stimulated; a test probe is coupled to a measurement access target on the area array, where the measurement access target is connected to fill metal in the signal routing layers of the area array package; and an electrical characteristic is measured by a tester coupled to the test probe to determine continuity of electrical paths through the area array of the circuit assembly.

### BACKGROUND OF THE INVENTION

During manufacture, circuit assemblies (e.g., printed circuit boards and Multi-Chip Modules) need to be tested for interconnect defects such as open solder joints, broken connectors, and bent or misaligned leads (e.g., pins, balls, or spring contacts). One way to test for such defects is via capacitive lead-frame testing. FIGS. 1 & 2 illustrate an exemplary setup for capacitive lead-frame testing. FIG. 1 illustrates a circuit assembly 100 comprising an integrated circuit (IC) package 102 and a printed circuit board 104. Enclosed within the IC package is an IC 106. The IC is bonded to the leads 108, 110 of a lead-frame via a plurality of bond wires 112, 114. The leads, in turn, are meant to be soldered to conductive traces on the printed circuit board. Note, however, that one of the leads 108 is not soldered to the printed circuit board, thereby resulting in an “open” defect.

Positioned above the IC package 102 is a capacitive lead-frame test assembly 116. The exemplary test assembly 116 shown comprises a sense plate 118, a ground plane 120, and a buffer 122. The test assembly is coupled to an alternating current (AC) detector 124. A first, grounded test probe, TP_1, is coupled to lead 110 of the IC package. A second test probe, TP_2, is coupled to lead 108 of the IC package. The second test probe is also coupled to an AC source 126.

FIG. 2 shows an equivalent circuit for the apparatus shown in FIG. 1. In the equivalent circuit, C_{Sense} is the capacitance seen between the sense plate 118 and the lead 108 being sensed, and C_{Joint} is the capacitance seen between the lead 108 and the conductive trace (on the printed circuit board) to which the lead is supposed to be soldered. The switch, S, represents the quality of the lead being tested. If the lead being tested is good, switch S is closed, and the capacitance seen by the AC detector is C_{Sense}. If the lead being tested is bad, switch S is open, and the capacitance seen by the AC detector is C_{Sense}*C_{Joint}/(C_{Sense}+C_{Joint}). If C_{Sense} is chosen to be significantly larger than any possible C_{Joint}, a bad lead will result in the AC detector seeing a capacitance near C_{Joint}. As a result, the AC detector must have sufficient resolution to distinguish C_{Sense} from C_{Joint}.

Additional and more detailed explanations of capacitive lead-frame testing are found in U.S. Pat. No. 5,557,209 of Crook et al. entitled “Identification of Pin-Open Faults by Capacitive Coupling Through the Integrated Circuit Package”, and in U.S. Pat. No. 5,498,964 of Kerschner entitled “Capacitive Electrode System for Detecting Open Solder Joints in Printed Circuit Assemblies”.

Over the years, various factors have interfered with the success of capacitive lead-frame testing. One factor is a lack of capacitive coupling between an IC lead-frame and a tester's sense plate. This problem is largely traced to the on-going miniaturization of IC packages and their lead-frames, as well as the imposition of ground shield and heat sinks between lead-frames and the sensor plate (some of which are internal to an IC's package). The miniaturization of lead-frames is also exacerbated by “area connection” packages. In an area connection package, the package's lead-frame is laid out as an array on a surface of the package, rather than in rows along the edges of the package. Examples of package area connections include ball grid arrays (BGAs; a lead-frame comprising a plurality of solder balls on a surface of a package) and land grid arrays (LGAs; a lead-frame comprising a plurality of stenciled or screened contact pads on a surface of a package). Area connection packages can be advantageous in that they often minimize the lengths of signal traces coupling a package's IC to its lead-frame. However, they can also interfere with capacitive lead-frame testing in that they sometimes make it difficult to position the sense plate of a capacitive lead-frame tester in close enough proximity to their lead-frames, they may have heat sinks or shielding between the IC and any external test probe.

One way to address some of the problems of IC miniaturization is disclosed in U.S. Pat. No. 6,087,842 and 6,097,203 of Parker et al. entitled “Integrated or Intrapackage Capability for Testing Electrical Continuity Between an Integrated Circuit and Other Circuitry”. These patents teach the placement of a capacitive sensor interior to an IC package, as illustrated in FIG. 3. If the placement of such sensor is carefully chosen, the capacitive coupling between the sensor and a package's lead-frame can be increased—in part because the interior placement of the capacitive sensor can circumvent shielding and heat dissipation structures of the IC package. In FIG. 3, an integrated circuit die 200 is attached to a substrate of base 202. The die 200 is electrically attached to bond wires 204 that in turn are attached to leads 206. The leads 206 are part of a lead frame that extends into the interior of the package. In FIG. 3, the package is depicted as having a separate cover 208. In general, packages may not have a separate cover.

The package assembly may include a grounded shield 210 or a heat sink 212. A capacitive probe 214 is included inside the package assembly. Probe 214 may be a ring or rectangular strip, near but not touching the bond wires 204 or the lead frame. The probe may have separate external electrical coupling 216 (ohmic or capacitive) for either a signal source or measurement circuitry, as shown in FIGS. 1-2. A capacitive test probe 218 may be placed on the outside surface of the base of the package.

One drawback to the internal test probe design of FIG. 3 is that it adds more layers to an integrated circuit package. As IC's become denser and with on-going miniaturization, area array packages or multi-chip modules are becoming more complex in order to effectively route signals, ground and power from the miniature die to the traces on the printed circuit assembly. In order to route the numerous signal, ground and power lines from the IC to the printed circuit assembly, these packages can have many routing layers. Therefore, adding more layers to such packages to support an internal test probe adds costs to package design and manufacturing. Also, some area array packages have internal power, ground and heat dissipating layers that can interfere with capacitive coupling with the IC.

There is a need for an internal test probe structure that overcomes the shortcomings of the prior art, without adding additional layers to the package.

### SUMMARY OF THE INVENTION

A device enabling testing continuities of electrical paths through an area array integrated circuit on a circuit assembly is presented. The device may comprise a measurement access target contact on the area array package. Fill metal within one or more layers of the area array package may be connected to the measurement access target contact.

A method for testing continuity of electrical paths through an area array integrated circuit on a circuit assembly is presented. The method may comprise stimulating one or more nodes of the circuit assembly, coupling a test probe with a measurement access target contact on the area array package that is connected to the fill metal of the signal routing layers of the area array package, measuring an electrical characteristic of the area array package on the circuit assembly with a tester coupled to the test probe to determine continuity of electrical paths through the area array on the circuit assembly.

### BRIEF DESCRIPTION OF THE DRAWINGS

A more complete appreciation of this invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 illustrates an exemplary set-up for capacitive testing of a circuit assembly;

FIG. 2 illustrates an exemplary circuit for capacitive testing;

FIG. 3 illustrates a side-cutaway view of an integrated circuit with an internal capacitive test plate;

FIGS. 4A-D illustrate top views of various signal routing layers of an exemplary area array package;

FIGS. 5A-D illustrate side cut-away views of the signal routing layers of an exemplary area array package as shown in FIGS. 4A-D;

FIG. 6 illustrates a top view of FIG. 4C showing an exemplary physical detail of the routing layer and fill metal;

FIG. 7 illustrates a top view of FIG. 4C showing a second exemplary physical layout of the routing layer and fill metal;

FIG. 8 illustrates a side cut-away view of an exemplary via between layers of an area array package;

FIG. 9 illustrates a blown-up, side view of an exemplary area array package with a measurement access target connected to the fill metal of the signal routing layers;

FIG. 10 illustrates a top view of an exemplary area array package of FIG. 9;

FIG. 11 illustrates an exemplary set-up for capacitive testing of the electrical paths of an area array package on a circuit assembly according to the invention; and

FIG. 12 illustrates a flow chart for an exemplary method for testing continuity of electrical paths through an area array package on a circuit assembly according to the invention.

### DETAILED DESCRIPTION OF THE INVENTION

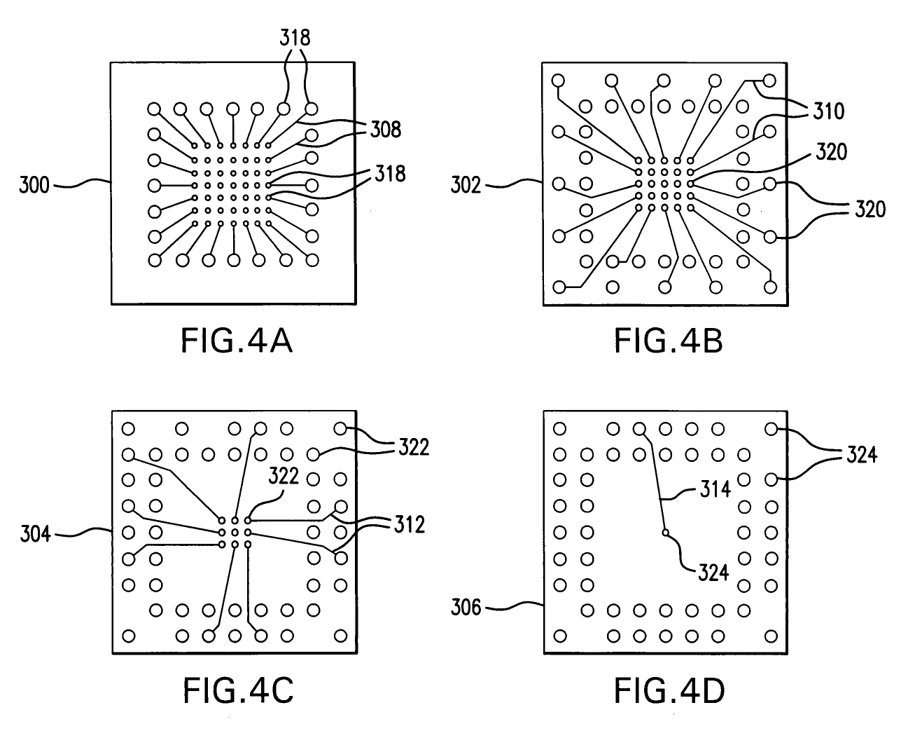

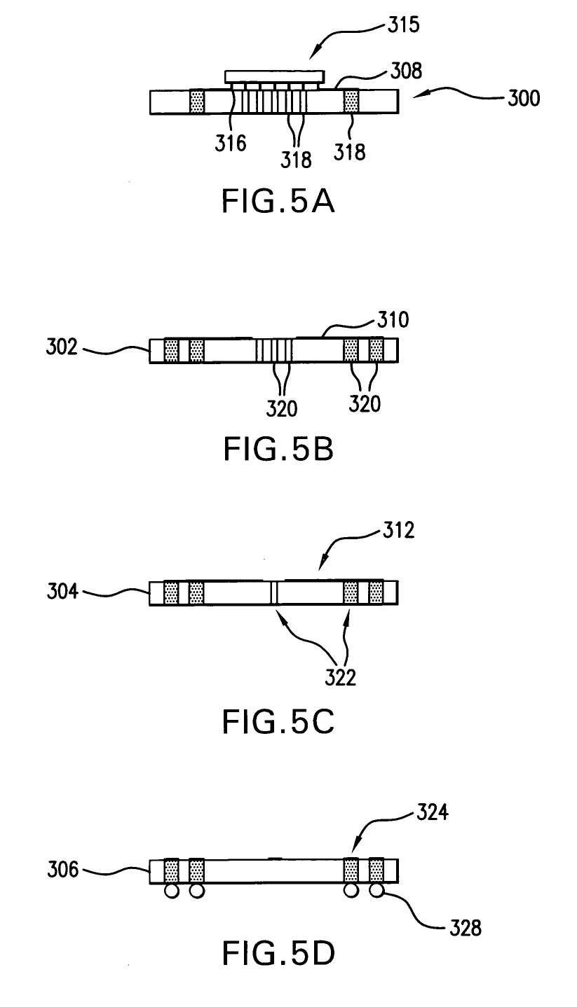

A typical area array package is made from a collection of laminated circuit layers as depicted in FIGS. 4A-D and FIGS. 5A-D. The layers 300-306 serve as a plane to route signal traces 308-314 from the IC die bonding bumps 316 on a very small pitch grid to much larger ball-grid array of solder balls 328 on the bottom of the package. The layers 300-306 may have vertical connections implemented with vias 318-324, to route signals between planes. The signal routing layers shown in FIGS. 4A-D and 5A-D are “logical” and do not show implementation detail.

Area Array packages also contain power and ground distribution planes that also serve to create controlled impedance environments for signals, and reduce outside interference. Power and ground planes will often shield any capacitive coupling from the signal traces to a capacitive sensor placed over the top of the package, reducing or eliminating the ability to test for open solder joints or missing solder balls. The ground and power planes between these signal planes are not shown in FIGS. 4A-D and 5A-D.

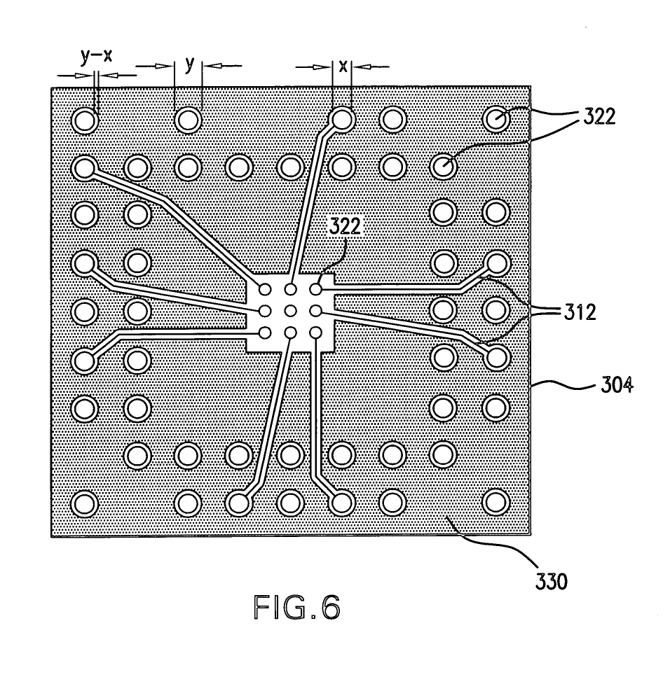

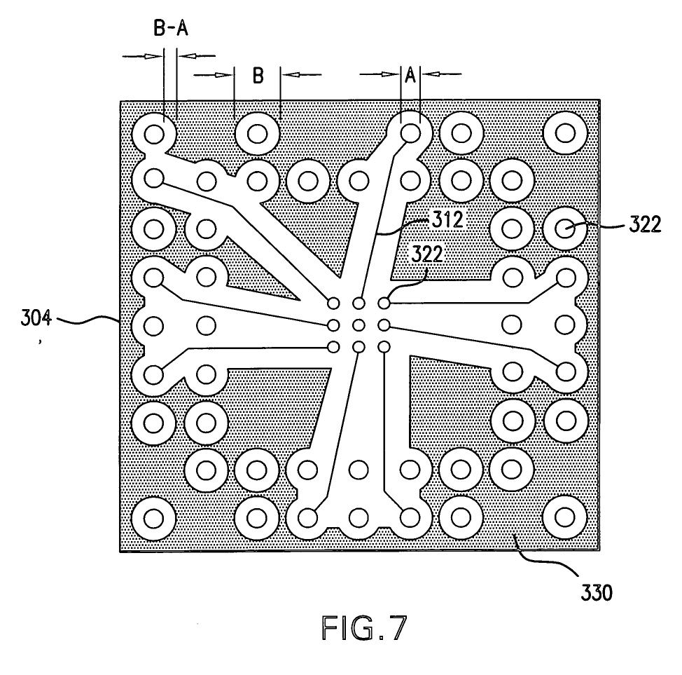

FIG. 6 shows layer 304 with the implementation detail added. Specifically, fill metal 330 is included or left on the layer after all the important features have been defined. Fill metal 330 covers most of the layer 304 between all of the other elements (vias, signal routing traces, etc.) of the layer 304. The fill metal 330 improves the mechanical flatness of the layer and also helps spread heat across the surface area of the layer. The fill metal 304 is electrically “floating”, as it typically not connected to anything, except by capacitance to power and ground planes (not shown) above and below layer 304 of the area array package. Fill metal may be maximized, as shown in FIG. 6, where all traces 312 and vias 322 are separated by a minimum distance (Y-X) specified in the routing layer design rules. As shown in FIG. 7, fill metal may also be separated by a distance (B-A) that is more than this minimum distance (Y-X) in some cases to minimize yield loss that could occur if fill metal became shorted to traces 312 or vias 322.

Between any signal trace metal 312 and via pad 322 and the fill metal 330, there will be a small capacitance. This capacitance will vary with the parameters of the traces and fill metal. For example, the trace and fill metal height will affect capacitance, as well as separation. The wider the separation, the lower the capacitance. The run-length of traces 312 alongside fill metal 330 will affect capacitance. The longer the run-length, the higher the capacitance. The dielectric constant of the insulating and laminating materials (not shown) of the layers (300-306) will also affect the capacitance between the fill metal 330 and the traces and vias. The fill metal to trace and via capacitance can be calculated from these characteristics.

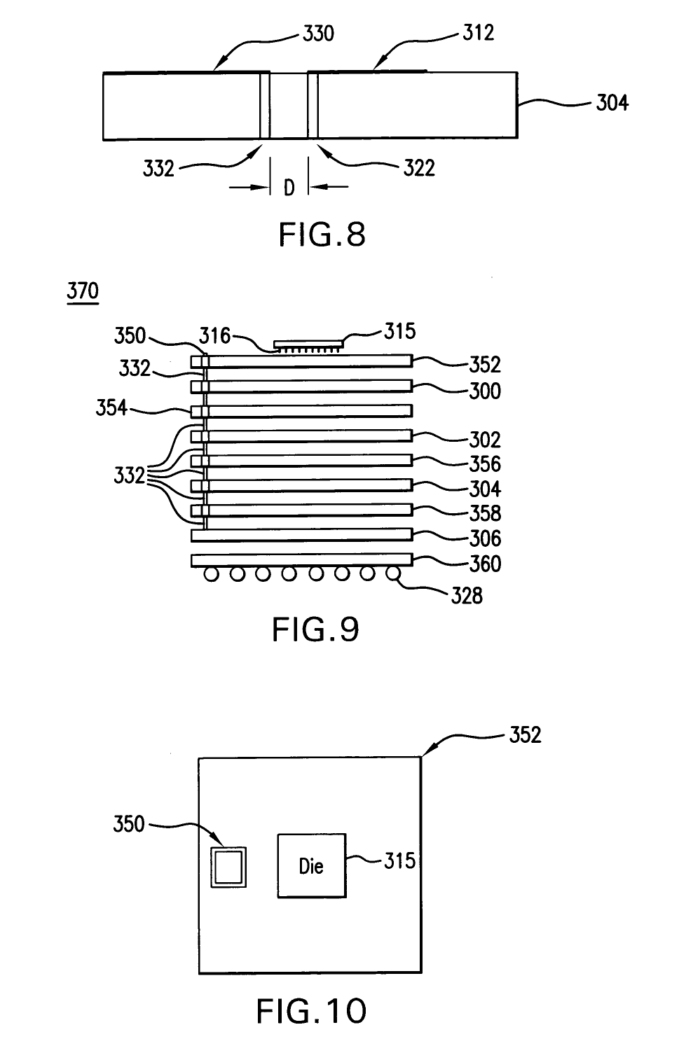

Extra vias 332 are used to connect the fill metal 330 of layers together electrically, as shown in FIG. 8. Normally, fill metal 330 is not connected from one layer to another layer within an area array package. However, since some signal traces may only appear on certain layers, fill metal areas of different layers may be stitched together to enhance capacitance between the fill metal and certain signal traces, as necessary.

This offers another opportunity to add capacitive coupling as well. Via height, width, separation and the layer dielectric constant all determine the capacitance between trace vias 322 and fill metal vias 332.

Capacitances that can be created between fill metal and signal traces will be quite small, usually well into the femtoFarad ranges. A practical target value that can be used for measuring open solder connections would be in the 10-20 femtoFarad range for each signal to fill metal.

FIGS. 9-10 illustrates an exemplary embodiment of an area array package 370 with an integrated circuit die 315 attached to a top ground layer 352 with signal trace/fill metal layers 300-306 interspersed between power 354, 358 and ground planes 352, 356, 360. Ball grid array 328 may be attached to the bottom ground plane 360. The fill metal 330 of signal trace/fill metal layers 300-306 is stitched together and brought to the top layer to connect with measurement access target 350 by means of fill metal connections or vias 332.

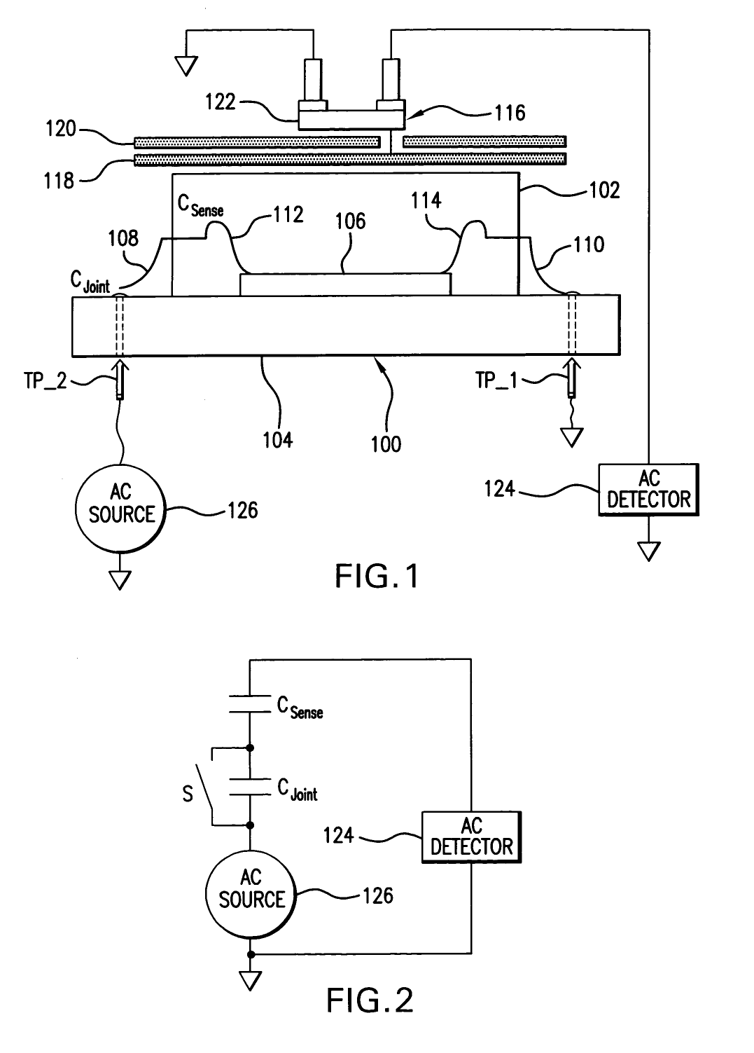

A measurement access target 350 is located on the top plane 352. Measurement access target 350 may be used to enable ohmic contact or capacitive coupling with a test probe. The test probe as shown in FIG. 1 may make ohmic contact by a small conductor attached to the bottom of the sense plate 118 that connects the sense plate directly to the fill metal target or measurement access target 350 on the top layer of the area array package.

Many integrated circuits will not have an exposed top surface due to the need to fill the top layer with an epoxy mixture to form a protective layer over the die. In such a case, the measurement access target 350 may be capacitively coupled to the sense plate 118 when it is brought in close proximity with it. The capacitance from the sense plate 118 to the measurement access target 350 should be significantly larger (e.g., 10×) than the larger capacitors between the fill metal 300 and the signal traces 308-314 of the area array package. This will prevent attenuation of the sensed signals.

Circuit designers may be concerned about the deliberate addition of capacitance between signals if they were to become larger than this. For example, if a die with several outputs and an input coupled capacitively to fill metal, the small capacitance to the input limits the additive effects of parallel outputs, even though many outputs could be pumping signal energy into the fill metal in parallel. Also, the fill metal has a substantially larger capacitance to the ground and power planes above and below it. This will divide and shunt most of the feedback signal away and minimize deleterious effects on circuit performance. However, this factor argues for keeping capacitive coupling to fill metal in lower (femtoFarad) ranges.

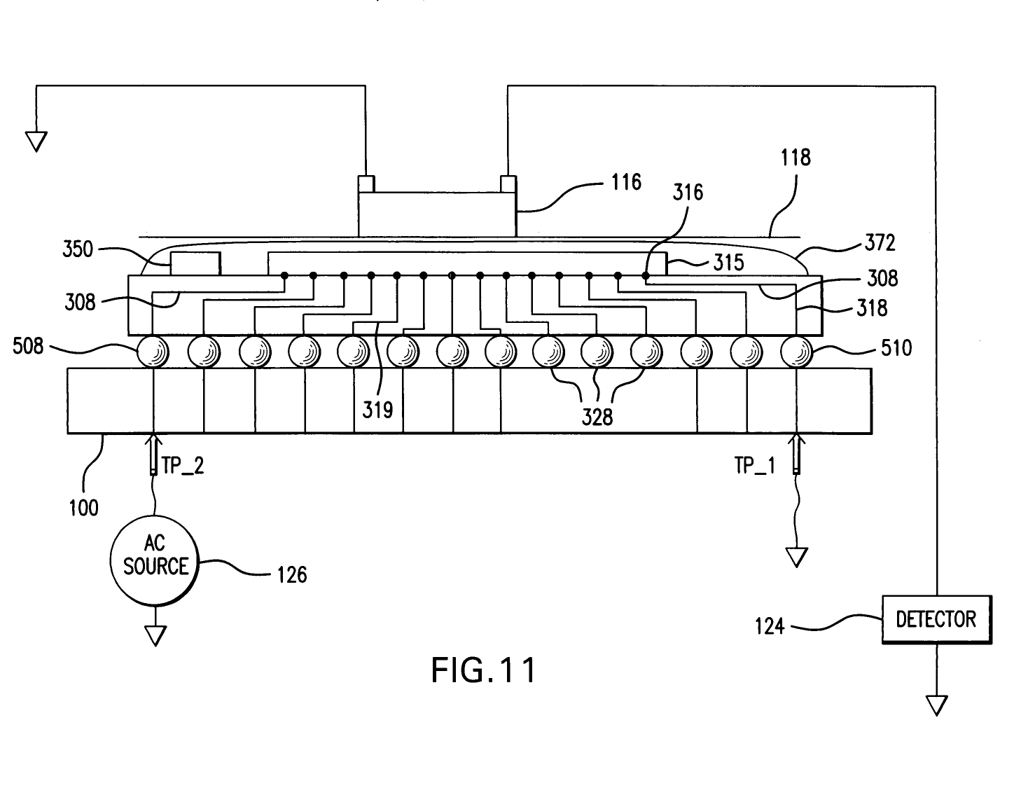

FIG. 11 illustrates an exemplary set-up for capacitive testing of electrical paths of an area array package 370 on a circuit assembly 100, which may comprise a printed circuit board. The area array package includes an IC 315. The IC 315 is attached to a top layer of an area array via a plurality of solder bumps 315 or other known technique. The bumps 315, in turn, are routed from the top layer 352 to an array of solder balls 328 on the bottom layer 360 via signal traces 308-314 and vias 318-324 of the various signal/fill metal layers 300-306 of the area array package 370. Solder balls 328 are soldered or connected to the circuit assembly 100. Note, however, that one of the balls 508 is not soldered to the printed circuit board, thereby resulting in an “open” defect.

Positioned above the IC package 370 is a capacitive test probe 116. The exemplary test probe 116 shown may comprise a sense plate 118, a ground plane 120, and a buffer 122, as shown in FIG. 1. The test assembly of FIG. 11 is coupled to an alternating current (AC) detector 124. A first, grounded test probe, TP_1, is coupled to solder ball 510 of the IC package 370. A second test probe, TP_2, is coupled to lead 508 of the IC package 370. The second test probe is also coupled to an AC source 126.

The capacitive test probe 116 is capacitively coupled to measurement access target 350 on the top layer 352 of the area array package 370. The measurement access target 350 is connected to the fill metal 330 of signal routing layers 300-306 by fill metal contact vias 332. The fill metal 330 of the signal routing layers 300-306 is capacitively coupled to the signal traces 308-314 of the signal routing layers 300-306. Note that the area array package 370 in FIG. 11 shows a protective encapsulation layer 372. Encapsulation layer 372 may be an epoxy or other known encapsulation material. If an encapsulation layer 372 is not used, than the test probe may be brought into ohmic contact with measurement access target 350.

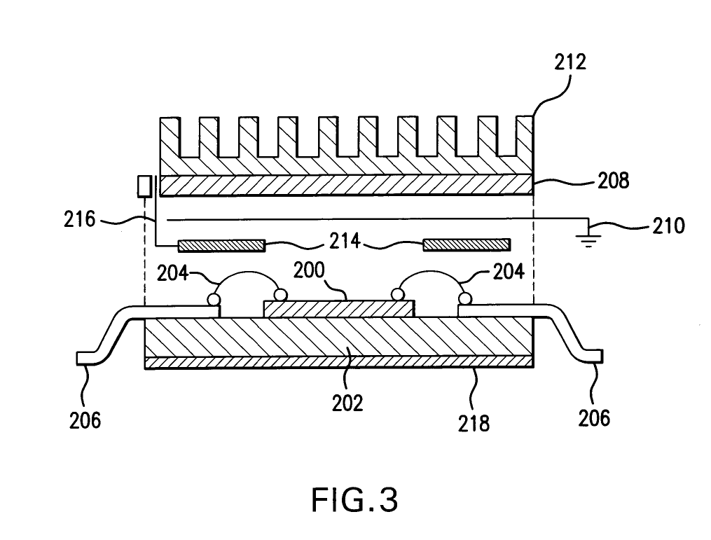

In operation, the test set-up of FIG. 11 would work similarly to the test set-up of FIGS. 1-3 with the fill metal providing capacitive coupling with the signal traces on the signal routing layers so that the continuity of electrical paths through the circuit assembly and area array can be assessed.

After preparing the circuit assembly 100 for test, one or more nodes (Tp_2) of the circuit assembly 100 are stimulated (e.g., via an AC signal source 126), while other nodes TP_1 of the circuit may be grounded (to reduce noise and extraneous signal pickup). If the area array is in good condition and solder ball 508 is properly connected to the circuit assembly 100, then the capacitance detected should be equal to a predetermined capacitance (C)±a predetermined error (ε). If the solder ball 508 is open or the area array is faulty, then a different capacitance will be detected. If this difference in capacitance is detectable by the capacitive test probe and detector and it is greater than ε, than it can be used to determine if an open exists in the electrical path between the printed circuit board and the area array at solder ball 508. A test of the circuit assembly 100 may continue with sequential stimulation of the nodes under the circuit assembly associated with each solder ball connection between the circuit assembly 100 and the area array package 370.

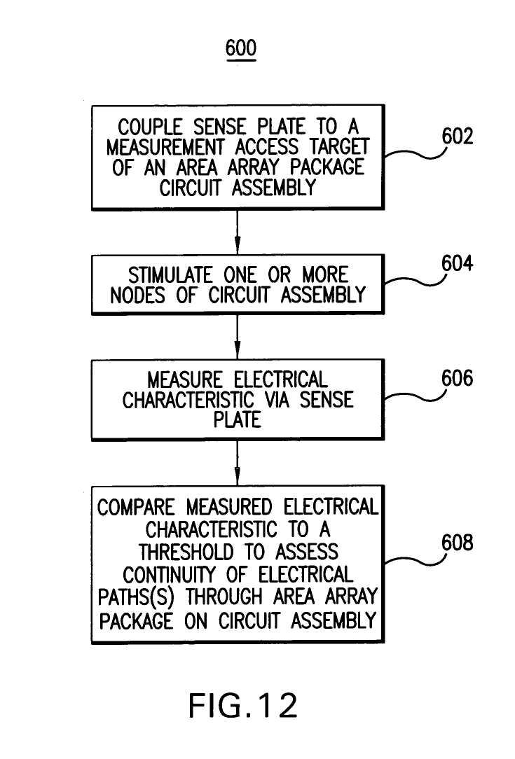

FIG. 12 illustrates a flow chart for an exemplary method 600 for testing continuity of electrical paths through an area array package on a circuit assembly according to an exemplary embodiment of the invention. The method 600 commences with the coupling 602 of a sense plate or test probe to a measurement access target that is connected to the fill metal of the signal routing layers of an area array package on a circuit assembly. Although, this coupling is described for illustration purposes herein as capacitive, the sensor plate or test probe may be coupled by other means, such as ohmic contact or inductively. One or more nodes of the circuit assembly are stimulated 604, and an electrical characteristic is measured 606 via the sensor plate or test probe coupled to the measurement access target. The measured electrical characteristic is then compared with at least one threshold to assess continuities of electrical paths through the circuit assembly 608.

While particular embodiments have been disclosed herein to illustrate and teach the invention, other embodiments are also anticipated. For example, while the vias 332 connecting the fill metal of the signal routing layers are shown substantially lined up, this is by no means the only embodiment and the vias 332 could be more than one between layers and could be placed wherever the vias make sense within the design rules of the signal routing layers. While the measured electrical characteristic disclosed was capacitance, for purposes of illustration, other electrical characteristics may be measured, such as inductance. Also, the electrical continuity of more than one area array package on a circuit assembly may be tested simultaneously using the teachings of the present invention. All of the above testing scenarios are within the scope of these teachings and anticipated by the inventor.

Although this preferred embodiment of the present invention has been disclosed for illustrative purposes, those skilled in the art will appreciate that various modifications, additions and substitutions are possible, without departing from the scope and spirit of the invention, resulting in equivalent embodiments that remain within the scope of the appended claims. The appended claims are intended to be construed to include such variations, except as limited by the prior art.

1. A device, comprising:
an integrated circuit package;
at least one signal routing layer with fill metal between traces and vias within the integrated circuit package; and
at least one measurement access target connected to at least one fill metal layer of the integrated circuit package.

2. The device according to claim 1, wherein the integrated circuit package is an area array package.

3. The device according to claim 1, wherein the integrated circuit package is a BGA type package.

4. The device according to claim 1, wherein the at least one measurement access target is configured to capacitively couple the fill metal within the integrated circuit package and a capacitive test probe of a tester.

5. The device according to claim 1, wherein the at least one measurement access target is configured to make ohmic contact between the fill metal within the integrated circuit package and a test probe of a tester.

6. A device for testing continuity of electrical paths through an area array integrated circuit of a circuit assembly, comprising:
at least one signal routing layer with fill metal within the area array; and
at least one measurement access target connected to the fill metal of the at least one signal routing layer.

7. The device according to claim 6, wherein the at least one measurement access target is configured to capacitively couple the fill metal of the area array package and a capacitive test probe of a tester.

8. The device according to claim 6, wherein the at least one measurement access target is configured to make ohmic contact between the fill metal of the area array package and a test probe of a tester.

9. A method for manufacturing an area array package, the method comprising:
forming at least one routing layers with fill metal;
forming at least one measurement access target; and
forming at least one connection between the fill metal and the at least one measurement access target.

10. A method for manufacturing an area array package, the method comprising:
forming more than one signal routing layers having fill metal;
electrically connecting the fill metal of the more than one signal routing layers;
forming at least one measurement access target; and
electrically connecting the at least one measurement access target to the fill metal.

11. A method for manufacturing an area array package in accordance with claim 10, using standard printed circuit board manufacturing techniques.

12. A method for testing continuity of electrical paths through an area array on a circuit assembly, comprising:
connecting fill metal between signal routing layers to an external measurement access target of the area array;
coupling a test probe to the measurement access target of the area array;
stimulating one or more nodes of the circuit assembly;
measuring an electrical characteristic; and
comparing the measured electrical characteristic to at least one threshold to assess continuities of electrical paths through the area array.

13. The method of claim 12, wherein the measured electrical characteristic is capacitance.

14. The method of claim 12, wherein the measured electrical characteristic is measured via a capacitive test probe coupled to the measurement access target.

15. The method of claim 12, wherein the measured electrical characteristic is inductance.

16. The method of claim 12, wherein the measured electrical characteristic is measured via an ohmic contact test probe coupled to the measurement access target.

17. The method of claim 12, where in the electrical characteristic is obtained by measuring a characteristic of an electrical path through the area array nodes, through the fill metal, through signal traces of the area array, through the measurement access target.

18. A method for determining continuity of electrical paths through a circuit assembly with area array package having signal routing layers, comprising:
stimulating one or more nodes of the circuit assembly;
coupling a test probe to a measurement access target of the area array package, wherein the measurement access target is connected with fill metal of the signal routing layers of the area array package;
measuring one or more electrical characteristics of the circuit assembly with a measuring device connected to the test probe; and
using one or more of the measured electrical characteristics to assess continuity of electrical paths through the area array of the circuit assembly.

19. The method according to claim 18, wherein the test probe is a capacitive test probe that is capacitively coupled to the measurement access target.

20. The method according to claim 18, wherein the test probe is ohmically coupled to the measurement access target.
